(19) United States
(12) Patent Application Publication
(10) Pub. No.: US 2008/0081409 A1
(43) Pub. Date: Apr. 3, 2008

(54) Method of Manufacturing Memory Device

(76) Inventors: Min-woo Song, Seongnam-si (KR); Seok-jun Won, Seoul (KR); Weon-hong Kim, Suwon-si (KR); Ju-youn Kim, Suwon-si (KR); Jung-min Park, Ansan-si (KR)

Correspondence Address: F. CHAU & ASSOCIATES, LLC, 130 WOODBURY ROAD, WOODBURY, NY, 11797, US

(21) Appl. No.: 11/858,674

(22) Filed: Sep. 20, 2007

(30) Foreign Application Priority Data
Oct. 2, 2006 (KR) 10-2006-0097302

(51) Int. Cl. H01L 21/8242

(52) U.S. Cl. 438/250; 257/E21.646

(57) ABSTRACT

A method of manufacturing a memory device that improves electrical characteristics of an MIM capacitor using a zirconium oxide film (ZrO₂) as a dielectric film includes: forming a lower metal electrode on a semiconductor substrate; forming a two or more-layered dielectric film including zirconium oxide films on the lower metal electrode; forming an upper metal electrode on the dielectric film; forming an MIM capacitor by patterning the upper metal electrode, the dielectric film, and the lower metal electrode; forming an interlayer insulating film covering the MIM capacitor; forming contacts in the insulating film; and performing heat treatment at a temperature range of 425 to 500° C.

### CROSS REFERENCE TO RELATED APPLICATION

This application claims priority from Korean Patent Application No. 10-2006-0097302 filed on Oct. 2, 2006 in the Korean Intellectual Property Office, the contents of which are herein incorporated by reference in their entirety.

### BACKGROUND OF THE INVENTION

1. Field of the Invention

The present disclosure is directed to a method of manufacturing a memory device, particularly a memory device that improves electric characteristics of MIM capacitors using zirconium oxide films (ZrO₂) as dielectric films.

2. Description of the Related Art

Recently, as high integration is required in memories, the design rule of memories has reduced and the operation speed of memories has increased. Capacitors that store information in DRAM (Dynamic Random Access Memory device) need to have the same or more capacitance in a smaller area as compared with those in the past. Accordingly, technologies for increasing capacitance of capacitors have been continually researched.

A method of increasing capacitance of capacitors is to reduce the EOT (equivalent oxide thickness) of dielectric films. A method of improving characteristics of capacitors that use zirconium oxide films having a small equivalent oxide thickness as dielectric films, particularly a metal-insulator-metal (hereinafter, called MIM) capacitor, has been researched.

As for a sin ale film of zirconium oxide film, however, it is limited in reducing the equivalent oxide thickness and defects due to the growth of crystal boundaries cause problems. Further, zirconium oxide films can be heat-treated to improve dielectric film characteristics, but the process and conditions are problematic.

### SUMMARY OF THE INVENTION

An embodiment of the present invention provides a method of manufacturing a memory device that improves electrical characteristics of MIM capacitors using zirconium oxide films as dielectric films.

An embodiment of the present invention is not limited to that mentioned above, and other objects of the present invention will be apparently understood by those skilled in the art through the following description.

According to an aspect of the present invention, there is provided a method of manufacturing a memory device, the method including forming a lower metal electrode on a semiconductor substrate, forming a two or more-layered dielectric film including zirconium oxide films on the lower metal electrode, forming an upper metal electrode on the dielectric film, forming an MIM capacitor by patterning the upper metal electrode, the dielectric film, and the lower metal electrode, forming an interlayer insulating film covering the MIM capacitor, forming contacts in the insulating film; and performing heat treatment at a temperature range of 425 to 500° C.

According to another aspect of the invention, there is provided a method of manufacturing a memory device, the method including forming a lower metal electrode on a semiconductor substrate, forming a first dielectric film including a zirconium oxide film on the lower metal electrode, forming a second dielectric film from one of an Al₂O₃ film, an HfO₂ film, a TiO₂ film, a La₂O₃ film, a Ta₂O₃ film, a PrO₂ film, or a combination thereof, on the first dielectric film, and forming a third dielectric film including a zirconium oxide film on the second dielectric film, wherein the second dielectric film is formed on the first dielectric film without heat treatment after the first dielectric film is formed.

### BRIEF DESCRIPTION OF THE DRAWINGS

The above and other features of embodiments of the present invention will become more apparent by describing in detail exemplary embodiments thereof with reference to the attached drawings.

FIG. 1 is a flowchart illustrating a method of manufacturing a memory device according to an embodiment of the invention.

FIGS. 2 to 12 are cross-sectional views sequentially illustrating a method of manufacturing a memory device according to an embodiment of the invention.

FIGS. 13 and 14 are graphs showing changes in an equivalent oxide film thickness and Vtoff with respect to heat treatment temperature and duration.

### DETAILED DESCRIPTION OF EXEMPLARY EMBODIMENTS

Features of embodiments of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Further, like reference numerals refer to like elements throughout the specification. The embodiments of the invention are not limited to those shown in the views, but include modifications in configuration formed on the basis of manufacturing processes. Further, components shown in the views of the invention may be somewhat enlarged or reduced for convenience of describing.

A method of manufacturing a memory device according to an embodiment of the invention will now be described in more detail with reference to accompanying drawings.

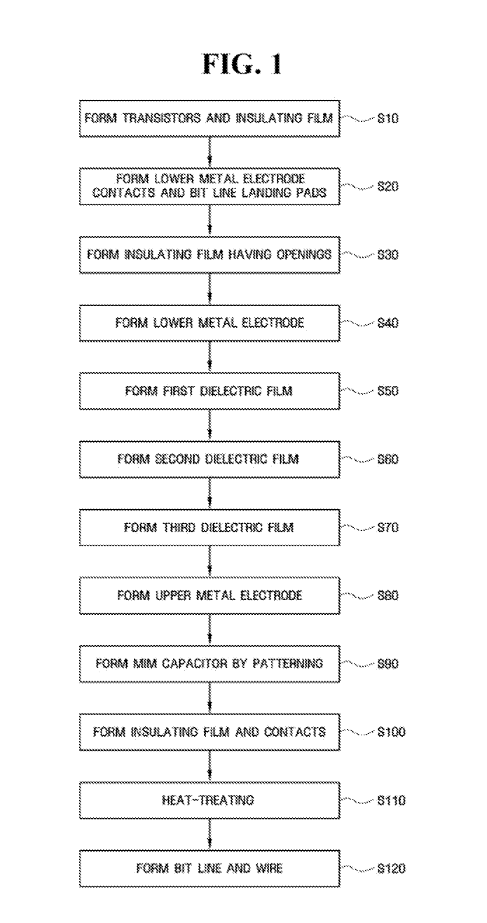

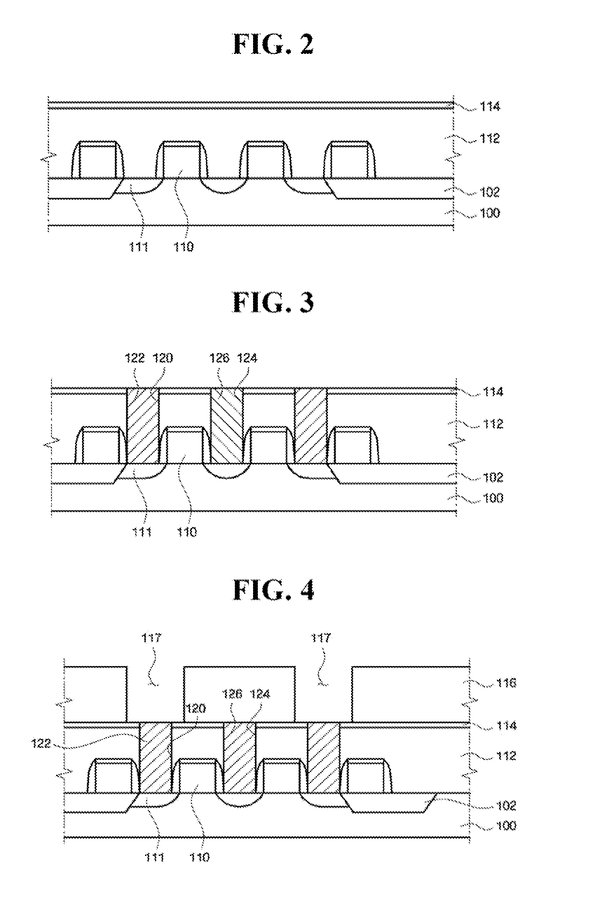

FIG. 1 is a flowchart illustrating a method of manufacturing a memory device according to an embodiment of the invention. FIGS. 2 to 12 are cross-sectional views sequentially illustrating individual processes in a method of manufacturing a memory device in that order according to an embodiment of the invention. FIG. 1 will be referred by individual processes of FIGS. 2 to 12 described below.

Referring to FIG. 2, transistors are first formed on a semiconductor substrate and an insulating film to cover the transistor is formed (S10).

In more detail, as shown in FIG. 2, gate electrodes 110 are formed on a semiconductor substrate 100 that is sectioned into active regions and field regions by an element separating film 102. Source/drain regions are formed by doping impurity ions into regions of the semiconductor substrate 100 between the gate electrodes 110. As a result, transistors including the gate electrode 110 and the source/drain region III are formed.

Following the transistors, an interlayer insulating film 112 and an etch stop film 114 are sequentially formed on the semiconductor substrate 110 with the transistors. A silicon oxide (SiO₂) may be used to form the interlayer insulating film 112. The etch stop film 114 may be SiON or SiN. Alternatively, etch stop film 114 may not be formed, if not necessary.

Referring to FIG. 3, lower metal electrode contacts 122 and bit line landing pads 126 that respectively contact with the source/drain regions 111 of the transistors are formed (S20).

In detail, the lower metal electrode contact 122 and the first bit line landing pad 126 that are electrically connected with the source/drain regions 111 of the transistor are formed within the interlayer insulating film 112 and etch stop film 114.

For example, the lower metal electrode contact 122 and first bit line landing pad 126 are formed by a method as follows. Etch masks that restrict regions to form the lower metal electrode contacts 122 and first bit line landing pads 126 are formed, and then first bit line contact holes 124 and lower metal electrode contact holes 120 that expose the lower source/drain regions 111 are completed by etching exposed portions of the interlayer insulating film 112 and the etch stop film 114 by the etch masks.

A conductive material is filled into the first bit line contact hole 124 and the lower metal electrode contact hole 120; thereafter the lower metal contact 122 and the first bit line contact 126 are formed by CMP or etch-back. The conductive material is filled in the lower metal electrode contact hole 120 and the first bit line contact hole 124, and may be W, Ti, TiN, or a combination thereof.

A barrier metal film (not shown) may be deposited before the metallic material is filled in the contact hole 124. The barrier metal film is provided to improve the contact properties of the contacts and to prevent diffusion of impurities during deposition of the metallic material, and may be, for example, TiN or Ti+TiN.

Now referring to FIG. 4, an interlayer insulating film 116 with openings 117 exposing the lower metal electrode contacts 122 is formed (S30). In other words, the interlayer insulating film 116 is formed on the resultant structure shown in FIG. 3. Subsequently, the openings 117 exposing the lower metal electrode contacts 122, which are landing pads contacting with the source regions 111, are formed by etching the interlayer insulating film 116.

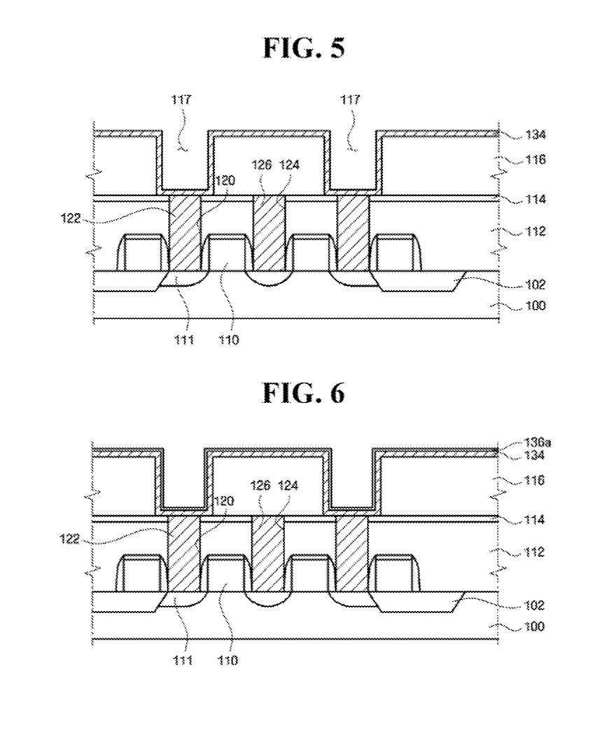

Referring to FIG. 5, following the interlayer insulating film, a lower metal electrode 134 is formed (S40).

The lower metal electrode 134 is a metal film that is electrically connected to the lower metal electrode contacts 122 at a lower portion thereof. The lower metal electrode 134 may be formed of TiN, TaN, WN, Ru, Pt, Ir, RuO₂, IrO₂, or combinations thereof.

The lower metal electrode 134 may be formed by MOCVD (Metal Organic Chemical Vapor Deposition).

An exemplary method of forming the lower metal electrode 134 from titanium nitride (TiN) is described below in more detail. The resultant structure of FIG. 4 is placed in a chamber within a first temperature range of about 300 to 450° C., or a second range of about 380 to 420° C., and at about 0.2 to 2.0 Torr, and then a TiN film covers the whole surface of the semiconductor substrate by supplying and reacting a precursor, one of TDMAT {tetrakis(dimethylamino)titanium; Ti[N(CH₃)₂]₄}, TDEAT {tetrakis(diethylamino)titanium, Ti[N(C₂H₅)₂]₄}, and TEMAT {tetrakis(ethylmethylamino)titanium; Ti[N(C₂H₅)CH₃]₄}, with ammonia gas (NH₃). The titanium nitride film is also formed in the openings 117. The ammonia gas (NH₃) is a reactant gas and its flow rate is kept within about 100 to 500sccm. An inert gas such as He or Ar may be added as a carrier gas.

The above process of forming the lower metal electrode 134 may further include removing impurities, such as carbon, in the titanium nitride film by applying N₂ and H₂ plasma treatment several times during the forming of the titanium nitride film. The plasma treatment may be applied at about 1 to 2 kW RF power.

The lower metal electrode 134 can be formed to be about 100 to 300 Å thick through the above process.

Subsequently, a dielectric film of two or more layers, including a zirconium oxide film, is now formed on the lower metal electrode 134. A dielectric film 136 including a first dielectric film 136a, second dielectric film 136b, and third dielectric film 136c is described hereafter by way of an example of the above dielectric film of two or more layers including zirconium oxide films, but is not limited to the following examples.

Referring to FIG. 6, the first dielectric film 136a is formed on the resultant structure of FIG. 5 (S50). The first dielectric film 136a may be a zirconium oxide film.

The first dielectric film 136a, for example, may be formed by ALD (Atomic Layer Deposition) or PEALD (Plasma Enhanced Atomic Layer Deposition). The atomic layer deposition and plasma enhanced atomic layer deposition may be applied at about 400° C. or less.

When the dielectric film 136 of zirconium oxide film undergoes the above process under the temperature condition, a heat treatment for improving the dielectric film characteristics of zirconium oxide film is not needed. However, the process of manufacturing a memory device is simplified by including the above heat treatment for improving the characteristics of the dielectric film of zirconium oxide film in another subsequent heat treatment, which is described below.

A method of forming a zirconium oxide film, the first dielectric film 136a, using plasma enhanced atomic layer deposition is now described hereafter. According to plasma enhanced atomic layer deposition, improved reactivity and a uniform film with a low impurity content can be achieved by using oxygen plasma as a reactant for depositing the zirconium oxide film. In other words, a uniform oxide film with a low impurity content can be achieved by processing oxygen plasma in a deposition chamber after injecting a source gas for deposition of zirconium oxide film. A zirconium oxide film can be formed having a desired thickness by repeating the above process. According to plasma enhanced atomic layer deposition, it is possible to decrease the temperature due to the use of plasma, such that a zirconium oxide film can be deposited within about 250 to 300° C.

A method of forming a zirconium oxide film, the first dielectric film 136a, on the lower metal electrode 134 by atomic layer deposition is now described. The method may be composed of repeated processes of supplying a source (zirconium) for the atomic layer deposition, and sequentially supplying a purge gas, an oxygen source, and a purge gas. The oxygen source may be H₂O, O₃, O radical, alcohol (e.g. isopropyl alcohol), D₂O, H₂O₂, O₂, N₂O, or NO. Alternatively, other precursors that are appropriate to an embodiment of the invention may be used within the range and aspect of the invention. According to atomic layer deposition, because mono layers are deposited one-by-one, step coverage is improved, and because deposition is applied at lower temperatures, a thermal budget is reduced.

In more detail, in the method of forming a zirconium oxide film of the first dielectric film 136a, source gas of TEMAZ [tetra-ethyl-methyl-amino zirconium; Zr(N(CH₃)(C₂H₅))₄] is supplied for about 0.1 to 15 seconds into a chamber at a temperature of about 250 to 350° C. The above source gas may be, other than the above TEMAZ, TDEAZ [tetrakis-diethylamino-zirconium; Zr(N(C₂H₅)₂)₄] or TEMAZ [tetrakis-methylethylamino-zirconium; Zr(N(CH₃)(C₂H₅))₄].

After the zirconium oxide film is formed, the source gas is purged by supplying N₂ or Ar gas for about 0.1 to 10 seconds. Reactant gas, such as O₂ or O₃, is then supplied for about 0.1 to 15 seconds. While supplying the above, RF power is maintained at about 0.1 to 1 kW. The first dielectric film 136a is formed accordingly on the lower metal electrode 134 of titanium insulating film; thereafter, unreacted materials are removed by supplying purge gas. The first dielectric film 136a of about 30 to 60 Å thick is formed by repeating the above process.

The afore-mentioned process may be applied at a temperature of 400° C. or less as described above, but the temperature is lower than the 425 to 500° C. range described below where the dielectric film characteristics of a zirconium oxide film are improved. Therefore, the dielectric film characteristics of the first dielectric film 136a may be substantially unchanged during this process.

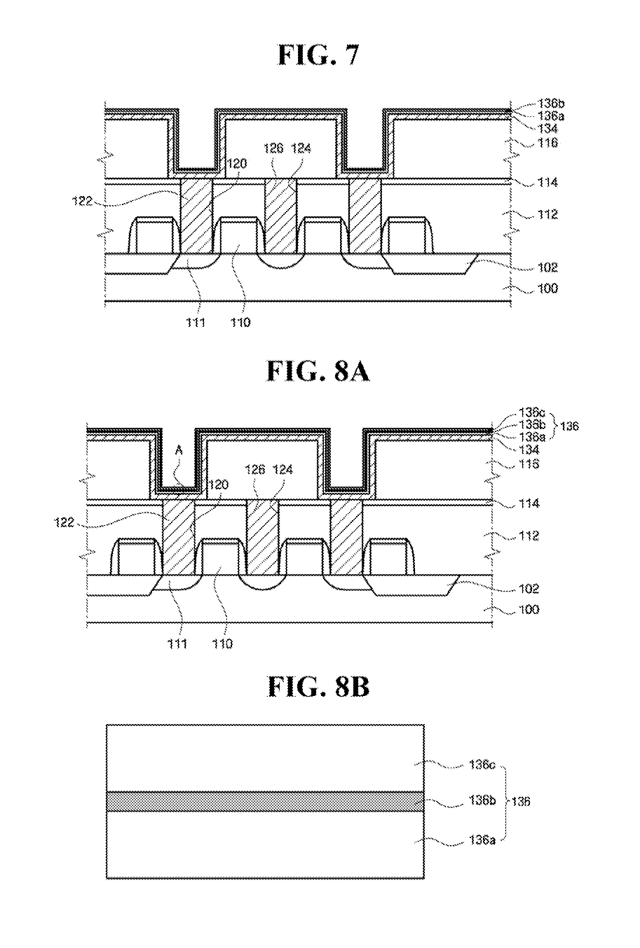

Referring to FIG. 7, the second dielectric film 136b is formed on the resultant structure of FIG. 6 (S60).

The second dielectric film 130b can prevent the growth of crystal boundaries of the zirconium oxide film. The second dielectric film 136b may be Al₂O₃, HfO₂, La₂O₃, Ta₂O₅, PrO₂, or combinations thereof, and may include nitride.

After being formed, the second dielectric film 136b may be nitrified before the third dielectric film 136c is formed. Plasma nitrification may be applied in a glow-discharged chamber at about 100 to 500 W RF power using any one of the gases selected from a group of NH₃, N₂, and N₂/H₂, at a temperature range of about 200 to 500° C. and at a pressure range of about 0.1 to 10 torr pressure for about 5 to 300 seconds. Further, the nitride film may be deposited by adding the above nitrification during the deposition cycle.

Similar to the first dielectric film 136a, the second dielectric film 136b may be formed by atomic layer deposition or plasma enhanced atomic layer deposition. The second dielectric film 136b may be formed at a temperature not more than about 400° C.

A method of forming the second dielectric film 136b on the first dielectric film 136a using atomic layer deposition is now described. The second dielectric film is formed of alumina (Al₂O₃) by way of an example. To form the alumina, a source gas of TMA (trimethyl aluminum) is supplied into a chamber at a temperature range of about 250 to 350° C. for 0.1 to 10 seconds. In addition to the TMA, the source gas may be AlCl₃, AlH₃N(CH₃)₃, C₆Hl₅AlO, (C₄H₉)₂AlH, (CH3)₂AlCl, (C₂H₅)₃Al or (C₄H₉)₃Al.

Thereafter, N₂ or Ar gas is supplied for about 0.1 to 10 seconds to purge the source gas and then the reactant gas of O₂ or O₃ is supplied for about 0.1 to 15 seconds, in which RF power is maintained to about 0.1 to 1 kW. The second dielectric film 136b of alumina is formed correspondingly on the first dielectric film 136a of zirconium oxide film; thereafter, unreacted materials are removed by supplying a purge gas for about 0.1 to 10 seconds. The second dielectric film 136b of alumina of about 2 to 20 Å thick is formed by repeating the above process.

After the second dielectric film 136b is formed, the third dielectric film 136c of about 30 to 60 Å is formed by applying the same process as in the method of forming the second dielectric film 136b of the alumina on the first dielectric film 136a (S70).

Referring now to FIG. 8A, similar to the first dielectric film 136a, the third dielectric film 136c may be formed by atomic layer deposition and plasma enhanced atomic layer deposition, for example, at 400° C. or less.

The present process is applied, as described above, at 400° C. or less, and the temperature is lower than about 425 to 500° C. (described below) where the dielectric film characteristics of a zirconium oxide film are improved. Therefore, the dielectric film characteristics of the first dielectric film 136a and the third dielectric film 136c may be substantially unchanged during this process.

The forming of the two- or more-layered dielectric film 136 that includes zirconium oxide film includes forming the first dielectric film 136a of the zirconium oxide film, forming the second dielectric film 136b of Al₂O₃, HFO₂, TiO₂, La₂O₃, Ta₂O₃, PrO₂, or compositions thereof on the first dielectric film 136a, and forming the third dielectric film 136c of zirconium oxide film on the second dielectric film 136b. The dielectric film characteristics of the two- or more-layered dielectric film 136 including the zirconium film can be improved by heat treatment, which is described in more detail below.

FIG. 8B is an expanded cross-sectional view of part A of FIG. 8A.

The second dielectric film 136b formed of alumina (Al₂O₃) is called the ZAZ dielectric film hereafter. FIG. 8B is a cross-sectional view of a ZAZ type dielectric film (zirconium oxide film/alumina/zirconium oxide film).

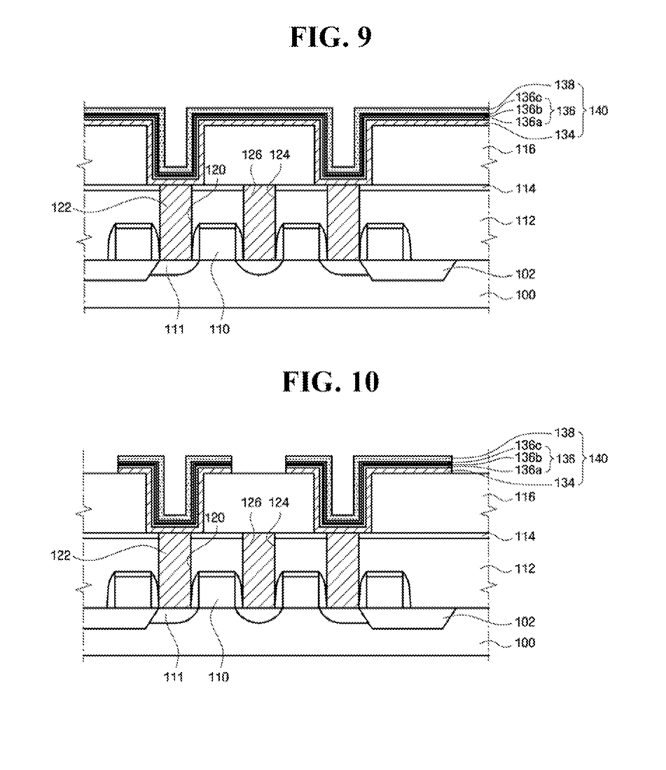

Relationships in the structures of FIGS. 1 to 3 are now described hereafter with reference to FIG. 8B. At least one of the first and third dielectric films 136a and 136c may have a thickness of about 40 Å. Further, the first and third dielectric films 136a and 136c may have substantially different thickness. As for the ZAZ structure, electrical characteristics of a capacitor 140 (see FIG. 9) may be improved when the thicknesses of zirconium oxide films, i.e. the first and third dielectric films 136a and 136c, are substantially different, rather than substantially the same.

However, the equivalent oxide thickness of the above ZAZ dielectric film is a maximum of about 9 Å, and its permittivity can be improved through additional heat treatment. Further, because the first, second, and third dielectric films 136a, 136b, 136c are formed by atomic layer deposition or plasma enhanced atomic layer deposition at about 400° C. or less and improving the dielectric film characteristics of zirconium oxide films is included in a subsequent heat treatment, a process of manufacturing a memory device is simplified. Therefore, the dielectric film characteristics of the first dielectric film 136a may be substantially unchanged during this process.

As shown in FIG. 9, an upper metal electrode 138 is formed on the dielectric film 136 formed in FIGS. 8A and 8B (S80).

The upper metal electrode 138 may be formed by a process substantially similar to that forming the lower metal electrode 134 on the semiconductor substrate. For example, similar to the lower metal electrode 136, the upper metal electrode 138 may be formed of TiN, TaN, WN, Ru, Pt, Ir, RuO₂, IrO₂, or combinations thereof. Further, the upper metal electrode 138 may also be formed by MOCVD (Metal Organic Chemical Vapor Deposition). A method of forming the upper metal electrode 138 when titanium nitride film (TiN) is used for the upper metal electrode 138 may be substantially the same as that for the lower metal electrode 134 described above with reference to FIG. 6 (S50).

As shown in FIG. 10, a metal-insulatar-metal (hereinafter, called MIM) capacitor 140 is formed by patterning the lower metal electrode 134, the first dielectric film 136a, the second dielectric film 136b, the third dielectric film 136c, and the upper metal electrode 138 (S90).

The formed capacitor 140 may be MIM capacitor and is composed of the upper metal electrode 138, the dielectric films 136a, 136b, and 136c, and the lower metal electrode 134. In particular, when the first and third dielectric films 136a, 136c are a zirconium oxide film and the second dielectric film 136b between the first and third dielectric films 136a and 136c is formed of alumina, it is called a ZAZ dielectric film. However, the dielectric films are not limited to the ZAZ type, and the structure of the dielectric films may be not only a zirconium oxide film/alumina oxide film, a alumina oxide film/zirconium oxide film, or alternative layers of a zirconium oxide film and an alumina oxide film, but the second dielectric film 136b may be an HfO₂ film, TiO₂ film, La₂O₃ film, Ta₂O₃ film, PrO₂ film or combinations thereof other than the alumina oxide film.

The capacitance of the formed MIM capacitor 140 is proportional to the surface area of the electrodes and the dielectric constant of a dielectric substance, and inversely proportional to the thickness of the dielectric film that is a distance between electrodes, more strictly the equivalent oxide thickness of the dielectric film. The formed capacitor 140 includes a high dielectric metal oxide film, such as a zirconium oxide film, so that it does not adversely effect the performance of elements and can decrease leaking electric current, in spite of a large thickness. However, the zirconium oxide film has a relatively low crystallization temperature and is thermally unstable, and is easily crystallized. Crystal boundaries that allow electric current to easily How in a metal oxide film are formed in a subsequent thermal annealing.

The formed MIM capacitor 140 is at least a two-layered structure including zirconium oxide films, because defects may occur in a single film of zirconium due to growth of crystal boundaries, causing a refresh property to deteriorate. Accordingly, because the formed MIM capacitor 140 is formed in at least a two-layered structure including a zirconium oxide film, and the zirconium oxide films are used as single films, defects and deterioration of the refresh property can be prevented.

A subsequent heat treatment, described below, is applied to the zirconium oxide film for improving characteristics of contacts 150 that contact the upper metal electrode 138 and second bit line contacts 146 after they are fanned.

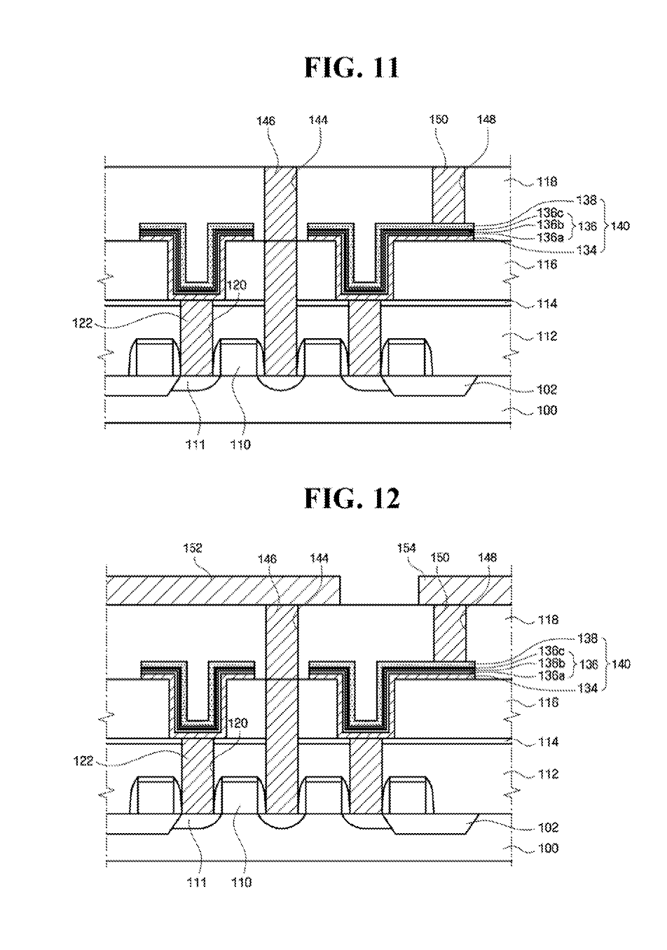

As shown in FIG. 11, an interlayer insulating film 118 that covers the MIM capacitor 140 is formed (S60), and then the contacts 150 that contact with the upper metal electrode 138 and the second bit line contacts 146 that contact with the first bit line contacts 126 are formed in the interlayer insulating film 118 (S100).

The contacts 150 contacting with the upper metal electrode 138 and the second bit line contacts 146 are formed by etching a part of the interlayer insulating film 118 using an etching mask that restrict regions to form the contacts 150 and the second bit line contacts 146. Upper metal electrode holes 148 are formed by etching the interlayer insulating film 118 until the upper metal electrode 138 is exposed and the second bit line contact holes 144 are formed by etching the interlayer insulating film 118 until the first bit line contacts 126 are exposed.

The upper metal electrode contacts 150 and the second bit line contacts 146 are completed by filling and etch-backing a metallic material in the upper metal electrode contact hole 148 and the second bit line contact hole 144. The metallic material filled in the upper metal electrode contact hole 148 and the second bit line contact hole 144 may be W, Ti, TiN, or combinations thereof.

A barrier metal film may be deposited before the metallic material is filled in the contact holes 148, 144. The barrier metal film is provided to improve a contact property and prevent diffusion of impurities during the deposition of the metallic material and may be, for example, TiN or Ti+TiN.

Heat treatment is then applied (S110).

Heat treatment is applied after the contact 150 contacting with the upper metal electrode 138 and the second bit line contact 146 contacting the first bit line contact 126 are formed. The heat treatment may be applied at a temperature range of about 425 to 500° C. for over 1 minute.

In particular, when a zirconium oxide film is used as the dielectric film, characteristics of the dielectric film depend on the heat treatment duration and temperature The heat treatment may be applied within about 425 to 500° C. The dielectric film 136 does not substantially deteriorate at 500° C. or less and where a difference in the equivalent oxide film thickness is small. In particular, when the heat treatment is applied at about 475° C., the thickness of the equivalent oxide film can be reduced without deterioration, thus the equivalent oxide film thickness is increased. At 500° C., the thickness of the equivalent oxide filmchanges less relative to 475° C., but the characteristics may deteriorate more.

The heat treatment may be maintained for over 1 minute. For a given temperature, when the beat treatment is maintained for more than 15 minutes, the thickness reduction of the equivalent oxide film reaches a maximum. The heat treatment has similar properties at 450° C. for 15 minutes and at 475° C for 5 minutes, such that it is desirable to maintain the heat treatment for about 5 to 15 minutes.

Accordingly, the heat treatment is possible within about 425 to 500° C. for over 1 minute, or within about 450 to 475° C. for about 5 to 15 minutes.

Dielectric characteristics of zirconium oxide film are improved through the heat treatment and the thickness of the equivalent oxide film is reduced. In addition, while the interface resistance between the lower metal electrode contact 122 and the lower electrode 134 is reduced, characteristics of the contact 150 contacting with the upper metal electrode 138 and the second bit line contact 146 is also improved.

In a method of manufacturing a memory device according to an embodiment of the invention, a specific heat treatment is not applied to the zirconium oxide film for improving dielectric film characteristics, but is rather included in another subsequent heat treatment for improving characteristics of contacts 150 that contact with the upper metal electrode 138 and second bit line contacts 146 after they are formed. Through the above heat treatment, it is possible to reduce the interface resistance of the lower electrode 134 of the lower electrode contacts 122 that are already formed before the capacitor is formed.

In a method of manufacturing a memory device, when the individual layers composing each element are exposed to high temperatures, they are under thermal stress, and adhesion of interlayer interfaces is decreased and defects may be caused in the interfaces. Therefore, by applying heat treatment in the above process, excessive heat is not needed in manufacturing the MIM capacitor 140, so that the MIM capacitor 140 having improved characteristics can be achieved.

As for the gases used for heat treatment and annealing, the gases for annealing may include inert gases such as N₂ and Ar, D₂ and H₂, and may include gas mixtures with inert gases.

Referring to FIG. 12, a memory device is completed by applying a subsequent process, such as forming a bit line 152 and a wire on the resultant structure of FIG. 11 (S120).

Experiment

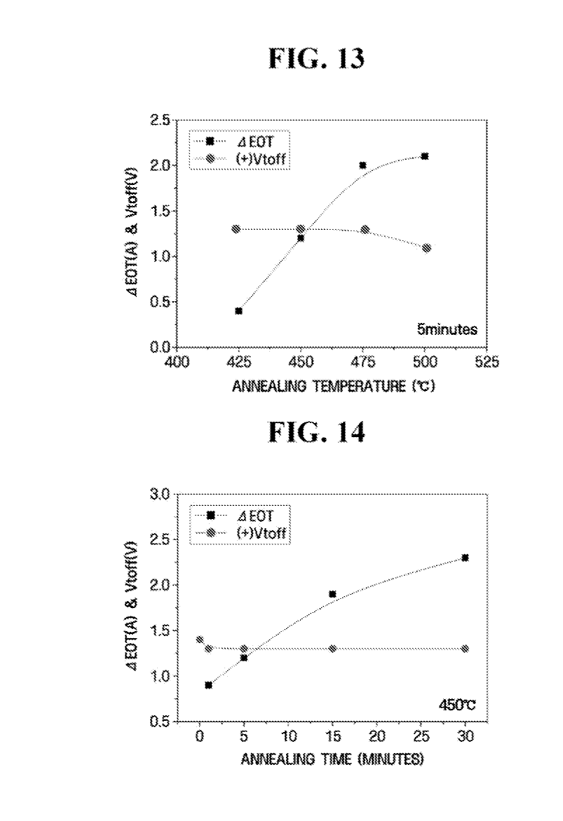

FIGS. 13 and 14 are graphs of characteristics obtained by applying heat treatment to a memory device manufactured by the method of manufacturing a memory device, according to an embodiment of the invention. The graphs in FIGS. 13 and 14 show changes in the thickness of the equivalent oxide film and Vtoff with respect to temperature and duration of the heat treatment. The Vtoff (Take-off Voltage) is defined as a voltage representing leaking electric current 1 fA/cell in a leaking electric current graph and is a reference for comparing characteristics of the leaking electric current. Typically, deterioration occurs as Vtoff is reduced.

The graph in FIG. 13 shows changes in the thickness of the equivalent oxide film and characteristics of Vtoff by heat treatment for 5 minutes. During heat treatment at 475° C., the thickness of the equivalent oxide film reduces by about 2 Å without deterioration of Vtoff, and even though a dielectric film of a ZAZ structure, an equivalent oxide film thickness of 8 Å or less could be finally obtained. The thickness of the equivalent oxide film at 500° C. did not substantially change relative to 475° C., but characteristics deteriorated. Accordingly, temperatures above 500° C. were determined to be temperatures where the dielectric film deteriorated.

The graph in FIG. 14 shows changes in the equivalent oxide film and the characteristics of Vtoff by heat treatment at 450° C. Under condition at 450° C. for 15 minutes and 475° C. for 5 minutes, the same characteristics appeared. In particular, reduction of the equivalent oxide film thickness reached the maximum for a duration greater than 15 minutes.

Accordingly, it could be seen from the graph that it is desirable to apply heat treatment within a temperature range of about 450 to 475° C. for about 5 to 15 minutes.

As for a memory device according to an embodiment of the invention, about 8 Å of the equivalent oxide film thickness could be obtained without deterioration of the leaking electric current characteristics, and it could be seen that deterioration of refresh characteristics appearing in single film of zirconium could be prevented.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limiting, but illustrative in all aspects.

As described above, according to a method of manufacturing a memory device of an embodiment of the invention, after a dielectric film is formed, although subsequent heat treatment after formation of contacts is applied without specific heat treatment, dielectric characteristics of zirconium oxide film are improved and the capacitance of MIM capacitor can also be improved.

Heat treatment for improving dielectric film characteristics of zirconium oxide film is included in another subsequent heat treatment for improving characteristics of a contact, so that the process can be simplified.

What is claimed is:

1. A method of manufacturing a memory device, the method comprising;
forming a lower metal electrode on a semiconductor substrate;
forming a two or more-layered dielectric film including zirconium oxide films on the lower metal electrode;
forming an upper metal electrode on the dielectric film;
forming an MIM capacitor by patterning the upper metal electrode, the dielectric film, and the lower metal electrode;
forming an interlayer insulating film covering the MIM capacitor;
forming contacts in the insulating film; and
performing heat treatment at a temperature range of 425 to 500° C.

2. The method of claim 1, wherein the forming of the dielectric film is performed without a heat treatment after forming of the dielectric film.

3. The method of claim 1, wherein the heat treatment is performed at 450 to 475° C.

4. The method of claim 3, wherein the heat treatment is performed for 5 to 15 minutes.

5. The method of claim 1 wherein the heat treatment is performed for 1 to 15 minutes.

6. The method of claim 5, wherein the heat treatment is performed for 5 to 15 minutes.

7. The method of claim 1, wherein the tormina of the dielectric film is performed using an ALD or PEALD process.

8. The method of claim 1, wherein the forming of the upper metal electrode and the lower metal electrode is performed using a MOCVD process.

9. The method of claim 1, wherein the forming of the dielectric film is performed at 400° C. or less.

10. The method of claim 1, wherein the forming of the dielectric film comprises:
forming a first dielectric film including a zirconium oxide film;
forming a second dielectric film from one of an Al₂O₃ film, an HfO₂ film, a TiO₂ film, a La₂O₃ film, a Ta₂O₃ film, a PrO₂ film, or a combination thereof, on the first dielectric film; and
forming a third dielectric film including a zirconium oxide film on the second dielectric film.

11. The method of claim 10, wherein the second dielectric film is formed on the first dielectric film without heat treatment after the first dielectric film is formed.

12. The method of claim 10, wherein the thickness of at least one of the first dielectric film and the third dielectric film is 40 Å or more.

13. The method of claim 10, wherein the first dielectric film and the third dielectric film have the thickness of 30 to 60 Å, and the thickness of the second dielectric film is 2 to 20 Å, respectively.

14. The method of claim 10, wherein the first dielectric film and the third dielectric film have substantially different thicknesses.

15. The method of claim 10, further comprising nitrifying the second dielectric film after the second dielectric film is formed and before the third dielectric film is formed.

16. The method of claim 1, wherein the heat treatment is performed using N₂, Ar, D₂, or H₂ gas, or a mixture thereof.

17. The method of claim 1, wherein the upper metal electrode and the lower metal electrode are formed of a titanium nitride film.

18. The method of claim 1, before the forming of the lower metal electrode, further comprising:
forming transistors on the semiconductor substrate;
forming an insulating film covering the transistors;
forming lower metal electrode contacts and bit line landing pads, which are in contact with source and drain regions of the transistors, in the insulating film; and
forming an insulating film having openings that exposes the landing pads being in contact with the source regions;
wherein the forming of the lower metal electrode includes forming the lower metal electrode in the opening,
the forming of the contacts includes forming contacts and bit line contacts that are in contact with the upper metal electrode, and
interface resistance between the lower electrode contacts and the lower electrode is reduced during the heat treatment.

19. A method of manufacturing a memory device, the method comprising:
forming a lower metal electrode on a semiconductor substrate;
forming a first dielectric film including a zirconium oxide film on the lower metal electrode;
forming a second dielectric film from one of an Al₂O₃ film, an HfO₂ film, a TiO₂ film, a La₂O₃ film, a Ta₂O₃ film, a PrO₂ film, or a combination thereof, on the first dielectric film; and
forming a third dielectric film including a zirconium oxide film on the second dielectric film;
wherein the second dielectric film is formed on the first dielectric film without heat treatment after the first dielectric film is formed.

20. The method of claim 19, further comprising,
forming an upper metal electrode on the dielectric film;
forming an MIM capacitor by patterning the upper metal electrode, the dielectric film, and the lower metal electrode;
forming an interlayer insulating film covering the MIM capacitor;
forming contacts in the insulating film; and
performing heat treatment at a temperature range of 425 to 500° C.
